(19) United States
(12) Patent Application Publication
(10) Pub. No.: US 2013/0280442 A1
(43) Pub. Date: Oct. 24, 2013

(54) Adhesion Promotion of Vapor Deposited Films

(71) Applicant: GVD Corporation, Cambridge, MA (US)

(72) Inventors: Karen K. Gleason, Cambridge, MA (US); James Samuel Peerless, Somerville, MA (US); W. Shannan O'Shaughnessy, Cambridge, MA (US)

(21) Appl. No.: 13/855,834

(22) Filed: Apr. 3, 2013

Related U.S. Application Data
(60) Provisional application No. 61/619,626, filed on Apr. 3, 2012.

(51) Int. Cl. C23C 16/448

(52) U.S. Cl. CPC C23C 16/448
USPC 427/586; 427/255.28; 427/255.29; 427/58

(57) ABSTRACT

Methods for improving the adhesion of vacuum deposited coatings to a wide variety of substrates are described herein. The methods include utilizing a thermal source to generate free radical species which are then contacted to the substrate to be coated. Chemical vapor deposition, particularly initiated chemical vapor deposition (iCVD) can be used to form polymer thin films in situ without the need to remove the substrate from the chamber or even return to atmospheric pressure. Significant improvements in substrate adhesion of the subsequently deposited films have been observed over a range of substrate and coating materials.

### CROSS REFERENCE TO RELATED APPLICATION

This application claims benefit of U.S. Provisional Application No. 61/619,626 filed Apr. 3, 2012, which is herein incorporated by reference in its entirety.

### FIELD OF THE INVENTION

This invention is in the field of vacuum deposited films, particularly improved adhesion of vacuum deposited films to a variety of substrates.

### BACKGROUND OF THE INVENTION

Many factors impact the utility of coatings. While the material properties of the coating itself and their suitability for the desired application are of primary importance, the interactions between the coating and the underlying substrate onto which it is deposited must also be considered. One of the most important of these interactions is coating adhesion. Adhesion is of critical importance for improving coating wear in friction applications, maximizing protective properties of coatings against liquids or vapors, and maintaining coating durability and utility in application environments that may act to delaminate the coating. As such, methods of improving coating adhesion across many different coating and substrate chemistries is highly desirable.

A wide range of approaches have been previously utilized to improve the adhesion of coatings. One approach is cleaning the substrate to remove debris and contaminants prior to coating application. This can serve to maximize favorable molecular interactions between coating and substrate and to avoid disruption of coating adhesion by areas of varying surface chemistry. If cleaning alone does not provide the necessary adhesion, surfaces can be physically modified to improve adhesion. This approach can take many forms, the most prevalent of which is surface roughening. By increasing the surface roughness of the substrate, additional contact area between coating and surface is created, providing more area over which favorable intermolecular interactions can occur.

When the approaches discussed above are not successful at imparting the desired coating adhesion, more aggressive means must be utilized, such as chemical means of adhesion. Such means can take the form of chemical modification of the substrate surface through the use of linkers or other molecules or energetic activation of the substrate through plasma, irradiation, or other means. These approaches may serve merely to improve the intermolecular interactions, though the most effective can form intermolecular bonds between coating and substrate. These methods, however, may not be suitable for all substrate materials and/or may not improve adhesion sufficiently for the desired application.

Therefore, there exists a need for improved methods for adhering coatings, particularly vacuum deposited coatings, to a variety of substrates.

It is therefore an object of the invention to provide improved methods for adhering coatings, particularly vacuum deposited coatings, to a variety of substrates.

### SUMMARY OF THE INVENTION

Methods for improving the adhesion of vacuum deposited coatings to a wide variety of substrates are described herein. The methods include utilizing an energy source to thermally generate free radical species which are then contacted to the substrate to be coated.

Chemical vapor deposition, particularly initiated chemical vapor deposition (iCVD), can be used to form polymer thin films in situ without the need to remove the substrate from the chamber or even return to atmospheric pressure. Significant improvements in substrate adhesion of the subsequently deposited films have been observed over a range of substrate and coating materials. For example, the coatings described herein retain at least 50, 60, 65, 70, 75, 80, 85, 90, 95, 96, 97, 98, or 99 percent of their initial (full) thickness when prepared using the methods described herein. In some embodiments, the thickness of the coatings described herein is substantially the same (e.g., 100%) as the initial (full) thickness.

The in situ nature of the approach may also be important to the chemical mechanism by which the enhanced adhesion occurs. While not desiring to be tied to any one theory, a possible mechanism by which free radical exposure enhances coating adhesion is through the abstraction of atoms from the substrate surface. These removed atoms may leave behind reactive sites from which covalent bonds can be formed to a subsequently deposited coating. If, however, the free radical exposure were to occur in a separate chamber, or if the method required the substrate be exposed to the atmosphere prior to coating, sites for covalent attachment would likely be quenched by oxygen or water.

Improving adhesion is of critical importance for improving coating wear in friction applications, maximizing protective properties of coatings against liquids or vapors, and maintaining coating durability and utility in application environments that may act to delaminate the coating.

### DETAILED DESCRIPTION OF THE INVENTION

### I. Definitions

The term “gaseous polymerizable species”, as used herein, refers to species which can be generated in the gas phase and upon polymerization form a polymeric coating, such as a conducting polymeric coating. The term “gaseous polymerizable species” includes monomers, oligomers, and metal-organic compounds. The gaseous polymerizable species disclosed herein may not necessarily be gases at room temperature and atmospheric pressure. If such species are liquids or solids, for example, they may be evaporated at reduced pressure or heated or both in order to perform the methods described herein.

“Activated”, as used herein, refers to chemical species acted upon by an energy source so as to render the species capable of forming a coating on the deposition substrate. Activated species include, but are not limited to, ions, and free radicals, such as di-radicals, and combinations thereof.

“End-capped polymer coating”, as used herein, refers to a polymer coating containing polymer chains originating and/or terminated in, or with, a specific chemical moiety. The polymer chains may be linear or branched.

“Energy Source”, as used herein, refers to the method of energy input into a gaseous system capable of activating precursor gas species so as to render them capable of forming a coating on the deposition substrate. Example energy sources include, but are not limited to, heated filaments, ionic plasma excitation, gamma irradiation, ultraviolet irradiation, infrared irradiation, and electron beam excitation.

“Filament”, as used herein, refers to resistively heated lengths of material capable of one or more of the following: thermal excitation of precursor gases, evaporative transfer of metal to the deposition substrate, or convective or radiative heating of the substrate.

“Gradient polymer coating”, as used herein, refers to deposited coating(s) in which one or more physical, chemical, or mechanical properties vary over the deposition thickness. Variation may be continuous or step-wise without limit to the number of steps or changes in different properties.

“Inert Gas”, as used herein, refers to a gas or gases which are not reactive under reaction conditions within the vacuum chamber.

“Vapor-phase coating system”, as used herein, refers to any system utilized to deposit a dry coating on a substrate without need for subsequent solvent evaporation or thermal curing. Examples include, but are not limited to, chemical vapor deposition (including atmospheric CVD), atomic layer deposition, and physical vapor deposition.

### II. Methods for Improving Adhesion

Methods for improving the adhesion of vacuum deposited coatings to a wide variety of substrates are described herein. The methods include utilizing an energy source to thermally excite molecules for the generation of free radical species which are then contacted to the substrate to be coated. In one embodiment the thermal source may be a hot wire filament array. In another embodiment, it may be an IR, UV, or other laser source. Other sources include ultrasound or microwave sources.

Chemical vapor deposition, particularly initiated chemical vapor deposition (iCVD), can be used to form polymer thin films in situ without the need to remove the substrate from the chamber or even return to atmospheric pressure. Significant improvements in substrate adhesion of the subsequently deposited films have been observed over a range of substrate and coating materials.

The in situ nature of the approach may also be important to the chemical mechanism by which the enhanced adhesion occurs. While not desiring to be tied to any one theory, a possible mechanism by which free radical exposure enhances coating adhesion is through the abstraction of atoms from the substrate surface. These removed atoms may leave behind reactive sites from which covalent bonds can be formed to a subsequently deposited coating. If, however, the free radical exposure were to occur in a separate chamber, or if the method required the substrate be exposed to the atmosphere prior to coating, sites for covalent attachment would likely be quenched by oxygen or water.

Techniques of film deposition may include, but are not limited to, hot filament CVD, initiated CVD, plasma CVD pulsed plasma CVD, UV activated

CVD, IR activated CVD, ALD, thermal CVD, oxidative CVD or plasma spray CVD. Materials prepared by these techniques for which the invented approach may be effective include, but are not limited to, polymers, ceramics, metals, and metal oxides. Specific vapor deposited polymers for which the invented approach may be effective include, but are not limited to, PTFE, acrylates, methacrylates, siloxane containing polymers, parylene, intrinsically conducting polymers, and copolymers of two or more of these.

A. Free Radicals

The generated free radical species may be of a similar chemical composition to the coating to be applied, or the initiator used to initiate polymerization, or may be different. In such embodiments, the free radical can be generated from one or more of the monomer and/or initiator species described below. In one embodiment, the free radical species may be generated from the decomposition of a free radical initiator. In a further embodiment the initiator may be a peroxide containing species, such as alkyl or aryl peroxides. Examples include, but are not limited to, dimethyl peroxide, di-t-butyl peroxide, and benzoyl peroxide. In particular embodiments, the initiator is a peroxide containing species which generates methyl radicals. Other radical generating species include azo compounds, sulfonate compounds, persulfates, and AIBN as well as the species described below for initiating polymerization.

In addition, the form of the free radical may also impact the efficacy of the approach. In one embodiment the free radical generating species and the conditions used for formation of the free radicals result in the formation of methyl radicals which then impinge on the surface. In some embodiments, the radicals generates are highly reactive and are sterically unhindered. For example, methyl radicals are both highly reactive and sterically unhindered, properties which may assist in the formation of reactive sites. Methyl radicals can be generated from a variety of species known in the art, including dimethyl peroxide. Other alkyl radicals can be generated from the corresponding dialkyl peroxide.

Conditions utilized for this approach are somewhat flexible provided that the generated free radicals are of sufficient concentration and duration. The substrate can be contacted with the free radicals for varying amounts of times such as at least one, 10, 15, 20, or 30 seconds or one, two, or five minutes. Treatment times as short as 10 seconds may be effective though optimal results have been observed with free radical exposure times of one minutes to several minutes, including, 2, 3, 4, 5, 6, 7, 8, 9, or 10 minutes or longer.

The exposure of the substrate to the free radicals can be conducted under various pressures, such as at least 0.1 mTorr, 1 mTorr, 10 mTorr, 100 mTorr, 200 mTorr, or 400 mTorr. In some embodiments, the substrate is contacted with the free radicals at a temperature less than one atmosphere.

The temperature at which the radical are generated can also vary depending on degradation temperature of the gas used to generate the radicals. In some embodiments, the thermal degradation of the precursor gas occurs at a temperature of about 40° C., 50° C., 75° C., 100° C., 150° C., 200° C., 250° C., 300° C., 350° C., 400° C., or 500° C.

B. Substrates

The methods described herein have utility across a wide range of coating chemistries and substrate materials. Substrates may be composed of, but are not limited to, polymer, metal, metal oxide, ceramic, biopolymer, natural rubber, or any combination thereof. Deposited coating chemistry may be of any form achievable by vapor deposition.

As mentioned above, improved coating adhesion has utility in a wide range of application areas. Coating areas may include, but are not limited to, mold release, industrial, semiconductor manufacturing, foam manufacturing, bioprocessing, pump and valve internals, automotive manufacturing, microelectronics protection, LEDs, OLEDS, MEMs, microfluidics, microelectronics, displays, and membranes, among others.

C. Initiators

In certain embodiments, a gaseous initiator can be used to initiate polymerization. In some embodiments, the gaseous initiator is selected from the group consisting of compounds of Formula I:

A-X—B (Formula I)

wherein, independently for each occurrence, A is hydrogen, alkyl, cycloalkyl, aryl, heteroaryl, aralkyl or heteroaralkyl; X is —O—O— or —N═N—; and B is hydrogen, alkyl, cycloalkyl, aryl, heteroaryl, aralkyl or heteroaralkyl.

In certain embodiments, the gaseous initiator is a compound of formula I, wherein A is alkyl.

In certain embodiments, the gaseous initiator is a compound of formula I, wherein A is hydrogen.

In certain embodiments, the gaseous initiator is a compound of formula I, wherein B is alkyl.

In certain embodiments, the gaseous initiator is a compound of formula I, wherein X is —O—O—.

In certain embodiments, the gaseous initiator is a compound of formula I, wherein X is —N═N—.

In certain embodiments, the gaseous initiator is a compound of formula I, wherein A is —C(CH₃)₃; and B is —C(CH₃)₃. In certain embodiments, the gaseous initiator of the invention is a compound of formula I, wherein A is —C(CH₃)₃; X is —O—O—; and B is —C(CH₃)₃.

In certain embodiments, the gaseous initiator is selected from the group consisting of hydrogen peroxide, alkyl or aryl peroxides (e.g., tert-butyl peroxide), hydroperoxides, halogens and nonoxidizing initiators, such as azo compounds (e.g., bis(1,1-dimethyl)diazene).

Note that “gaseous” initiator encompasses initiators which may be liquids or solids at standard temperature and pressure (STP), but upon heating may be vaporized and fed into the chemical vapor deposition reactor.

D. Monomer Species

The coatings can be formed using a variety of different monomeric species, such as difluorocarbene, ethylenedioxythiophene, trivinyltrimethylcyclotrisiloxane, hydroxyethylmethacrylate, vinylpyrrolidone, functional acrylates, functional methacrylates, diacrylates, dimethacrylates, cyclic siloxane containing compounds, and siloxane compounds containing unsaturated organic moieties. Other suitable coating materials include graphene, graphite, molybdenum disulfide, tungsten disulfide, electrically conductive coatings, electrically insulating coatings, and hydrophilic coatings.

Electrically conducting polymers include, but are not limited to, aromatic or heteroaromatic polymers, such polyfluorenes, polyphenylenes, polypyrenes, polyazulenes, polynapthtalenese, polypyrroles, polycarbazoles, polyindoles, polyazepines, polyanilines, polythiophenes, poly(3,4-ethylenedioxythiophene (PEDOT), poly(p-phenylene sulfide), polyacetylenes, and poly(p-phenylene vinylene).

Examples of electrically insulating polymers include, but are not limited to, rubber-like polymers and plastics. Electrically insulating polymers may be highly thermally conductive if required for specific applications.

Exemplary monomers are represented by the structures below:

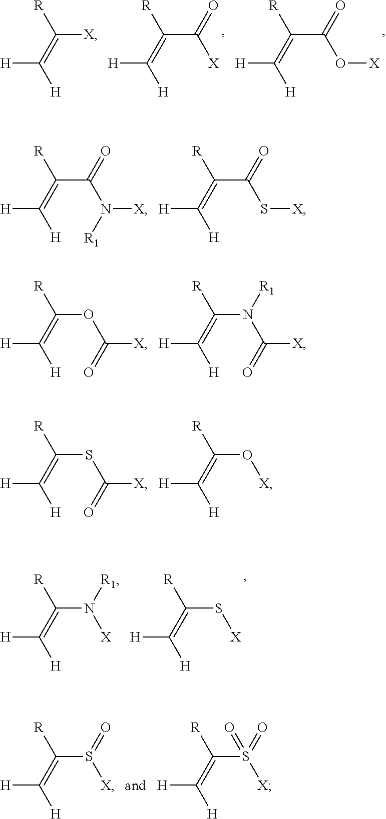

wherein R and R₁ are independently selected from the group consisting of hydrogen, alkyl, bromine, chlorine, hydroxyl, alkyoxy, aryloxy, carboxyl, amino, acylamino, amido, carbamoyl, sulfhydryl, sulfonate, and sulfoxido; X is selected from the group consisting of hydrogen alkyl, cycloalkyl, heteocycloalkyl, aryl, heteroaryl, aralkyl, heteoaralkyl, and —(CH₂)ₙY; Y is selected from the group consisting of hydrogen, alkyl, cycloalkyl, heterocycloalkyl, aryl, heteroaryl, aralkyl, heteoaralkyl, nitro, halo, hydroxyl, alkyoxy, aryloxy, carboxyl, heteroaryloxy, amino, acylamino, amido, carbamoyl, sulfhydryl, sulfonate, and sulfoxido; and n is 1-10 inclusive.

In some embodiments, R is hydrogen or methyl, X is hydrogen or —(CH₂)ₙY, where Y is alkyl, cycloalkyl, heterocycloalkyl, aryl, nitro, halo, hydroxyl, alkyloxy, aryloxy, amino, acylamino, amido, or carbamoyl, and n is 3-8 inclusive. In other embodiments, R, X and n are as defined above and Y is hydrogen, heterocyloalkyl, or oxirane.

i. Fluorinated Monomers

CVD techniques can be used to polymerize fluorinated monomers containing vinyl bonds. Fluoropolymers, if they can be dissolved at all, require the use of harsh solvents for liquid-base film casting process. Vapor-based processes avoid the difficulties resulting from surface tension and nonwetting effects, allowing ultrathin films (<10 nm) to be applied to virtually any substrate. Thus, CVD is highly suitable for the deposition of fluoropolymers. Suitable fluorinated monomers include, but are not limited to, perfluoroalkylethyl methacrylate (CH2=C(CH3)COOCH2CH2-(CF2)nCF3, perfluoroalkyl acrylates (CH2=CHCOOCH2CH2(CF2)7-CF3) and perfluoroalkenes (CF2=CF—(CF2)n-CF3) where n=5-13.

In addition to homopolymers, CVD copolymers of one or more fluorinated monomers with other monovinyl, divinyl, trivinyl, and cyclic monomers can be used to tune surface energy, surface roughness, degree of crystallinity, thermal stability, and mechanical properties.

ii. Polysiloxane Coatings

CVD techniques can also be used to prepare polysiloxane (“silicone”) coatings formed from siloxane-containing monomers including, but not limited to, trivinyl-trimethyl-cyclotrisiloxane (V3D3). The resulting material [poly(V3D3)] is a highly cross-linked matrix of silicone and hydrocarbon chemistries. The dense networked structure renders this material more resistant to swelling and dissolution compared with coatings having little or no crosslinking, such as conventional silicones or parylene.

In some embodiments, the polymer contains both fluorine and siloxane moieties. For example, in particular embodiments, the coating contains a polymer containing siloxane moieties terminated by fluorine containing groups. In one embodiment, the siloxane containing polymer is poly(trivinyl-trimethyl-cyclotrisiloxane) and the fluorine containing termination groups are composed of fragments of perfluorobutane sulfonate.

The substrate can be contacted with the monomer species for varying amounts of times such as at least one, 10, 15, 20, or 30 seconds or one, two, or five minutes or longer. Reaction times can vary depending on the material to be coated and the desired thickness of the coating. Treatment times as short as 10 seconds may be effective though optimal results have been observed with free radical exposure times of one minutes to several minutes, including, 2, 3, 4, 5, 6, 7, 8, 9, or 10 minutes or longer.

The exposure of the substrate to the free radicals can be conducted under various pressures, such as at least 0.1 mTorr, 1 mTorr, 10 mTorr, 100 mTorr, 200 mTorr, or 400 mTorr. In some embodiments, the substrate is contacted with the monomer or monomers at a temperature less than one atmosphere. The temperature at which the radical are generated can also vary. In some embodiments, the polymerization occurs at a temperature of about 40° C., 50° C., 75° C., 100° C., 150° C., 200° C., 250° C., 300° C., 350° C., 400° C., or 500° C.

E. Coating Properties

The methods described herein produce coatings that exhibit significant improvement in adherence strength to the substrate compared to coatings applied to a substrate that has not been contacted with radical species. For example, tert-butyl Peroxide, at a pressure of 400 mTorr, was decomposed over a filament at 350° C. for a treatment time of 5 minutes on a silicon wafer. Subsequently, 260 nm of PTFE was deposited by initiated CVD. A control sample of 260 nm of PTFE was formed on an untreated wafer for comparison. Both samples were scored with a diamond tip pen, to promote coating delamination, and boiled for 10 minutes in deionized water. The treated sample resists coating delamination while the untreated sample delaminated almost entirely.

In some embodiments, the coatings described herein retain at least 50, 60, 65, 70, 75, 80, 85, 90, 95, 96, 97, 98, or 99 percent of their initial (full) thickness when prepared using the methods described herein. In some embodiments, the thickness of the coatings described herein is substantially the same (e.g., 100%) as the initial (full) thickness. In particular embodiments, the coatings retain the amount of their full thickness listed above when scored with a diamond tip pen and immersed in boiling water for at least 10 minutes.

In some embodiments, the degree of delamination of the control compared to the claimed methods is evaluated visually. In other embodiments, the film thickness can be measured using techniques known in the art, such as ASTM, profilometry, and the like.

### EXAMPLES

### Example 1

### Adhesion of Coating to Substrate

Tert-butyl Peroxide, at a pressure of 400 mTorr, was decomposed over a filament at 350° C. for a treatment time of 5 minutes on a silicon wafer. Subsequently, 260 nm of PTFE was deposited by initiated CVD. A control sample of 260 nm of PTFE was formed on an untreated wafer for comparison. Both samples were scored with a diamond tip pen, to promote coating delamination, and boiled for 10 minutes in deionized water. The treated sample resists coating delamination while the untreated sample delaminates almost entirely.

Unless defined otherwise, all technical and scientific terms used herein have the same meanings as commonly understood by one of skill in the art to which the disclosed invention belongs. Publications cited herein and the materials for which they are cited are specifically incorporated by reference.

Those skilled in the art will recognize, or be able to ascertain using no more than routine experimentation, many equivalents to the specific embodiments of the invention described herein. Such equivalents are intended to be encompassed by the following claims.

We claim:

1. A method for improving adhesion of a vapor deposited material on an underlying substrate, the method comprising contacting the substrate with a plurality of free radical species and vapor depositing a coating material onto the substrate.

2. The method of claim 1, wherein the free radical species are generated by thermal degradation of a precursor gas.

3. The method of claim 2, wherein the precursor gas comprises a free radical initiator, a monomer, or combinations thereof

4. The method of claim 2, wherein the free radicals are generated by UV, IR, or laser degradation of the precursor gas.

5. The method of claim 2, wherein the free radicals are generated by plasma excitation of the precursor gas.

6. The method of claim 3 wherein the precursor gas comprises a peroxide containing species.

7. The method of claim 6 wherein the thermal degradation occurs over a heated filament.

8. The method of claim 7, wherein the heated filament achieves a temperature sufficient to produce methyl radical species.

9. The method of claim 1 wherein the vapor deposited material is formed at a pressure less than 1 atm absolute.

10. The method of claim 1 wherein the contacting of the free radicals occurs at a pressure less than 1 atm absolute.

11. The method of claim 1 wherein the substrate comprises metal, metal oxide, polymer, ceramic, or combinations thereof.

12. The method of claim 1 wherein the exposure occurs for a time period selected from the group consisting of at least 1 sec, 10 sec, 30 seconds, 1 minute, 2 minutes, or 5 minutes.

13. The method of claim 1 wherein the exposure occurs at a pressure selected from the group consisting of at least 0.1 mTorr, 1 mTorr, 10 mTorr, 100 mTorr, 200 mTorr, or 400 mTorr.

14. The method of claim 1 wherein the thermal degradation of the precursor gas occurs at a temperature selected from the group consisting of 40° C., 50° C., 75° C., 100° C., 150° C., 200° C., 250° C., 300° C., 350° C., 400° C., or 500° C.

15. The method of claim 1, wherein the coating material is PTFE.

16. The method of claim 1, wherein the coating material is a siloxane containing polymer.

17. The method of claim 16, wherein the siloxane-containing polymer is polytrivinyltrimethylcyclotrisiloxane, polytetravinyltetramethylcyclotetrasiloxane, or combinations thereof

18. The method of claim 1, wherein the coating material is parylene.

19. The method of claim 1, wherein the coating material is a conducting polymer.

20. The method of claim 19, wherein the conducting polymer is PEDOT.

21. The method of claim 1, wherein the coating material is an acrylate/methacrylate polymer.
